(19) United States
(12) Patent Application Publication
(10) Pub. No.: US 2010/0103006 A1
(43) Pub. Date: Apr. 29, 2010

(54) ADC TEST CIRCUIT AND SEMICONDUCTOR DEVICE

(75) Inventors: Masakazu Miyake, Yokohama-shi (JP); Kazutoshi Shimizu, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/563,501

(22) Filed: Sep. 21, 2009

(30) Foreign Application Priority Data
Oct. 23, 2008 (JP) 2008-272975

(51) Int. Cl. H03M 1/10; H03M 1/12

(52) U.S. Cl. 341/120; 341/155

(57) ABSTRACT

An ADC test circuit has an expected value generator configured to generate an expected value signal for a converted output signal of an ADC (Analog to Digital Converter), a test signal generator configured to generate an input test signal applied to the ADC based on the expected value signal, and a comparator configured to compare the converted output signal of the ADC corresponding to the applied input test signal with the expected value signal.

### CROSS REFERENCE TO RELATED APPLICATIONS

This application is based upon and claims the benefit of priority from the prior Japanese Patent Application No. 2008-272975, filed on Oct. 23, 2008, the entire contents of which are incorporated herein by reference.

### BACKGROUND OF THE INVENTION

1. Field of the Invention

The present invention relates to an ADC (Analog to Digital Converter) test circuit to test a result of analog to digital conversion by the ADC and a semiconductor device therefor.

2. Related Art

When processing audio and video signals on digital home electric appliances etc., it is generally performed that analog signals are digitally coded to perform operation processing. An ADC is a kind of IP (Intellectual Property) used for the coding process. With recent market requirement of high speed operation and high quality, the ADCs with high sampling rate (over 100 MHz) and with resolution over 10 bits have been widely used for these appliances.

As the resolution of the ADC becomes high, there is a higher possibility that the ADC outputs error signals. Therefore, it is necessary to test whether or not the conversion accuracy of the ADC fulfills specification. In order to test the ADC, there is a way generally known on the purpose of comparing the conversion output signal of the analog signal input to ADC with the expected value signal corresponding to it. However, when the sampling rate is high and the resolution is also high, it is difficult to test the ADC correctly because the characteristics of the ADC gets worse due to the influence of the increased switching noise of output buffer in the ADC, which may cause malfunction in a commercial field.

Furthermore, a system LSI having a plurality channels of ADCs needs an enormous number of signal terminals to output all channels of ADC signals including control signals for cutout test using of TESTMUX. When the number of these signal terminals exceeds that of the LSI signal pins, it is necessary to decrease the number of the simultaneously observable channels. This decreases the number of the channels capable of testing simultaneously, and increases number of times of the test and test cost.

In JP-A. No. 2006-324745 (Kokai) (hereinafter, “patent Document 1”), an input test signal AIN is inputted to an ADC, and a converted output signal of the ADC is compared with an expected value signal EXPECT separately generated outside in an LSI. A signal of only 1 bit indicative of the comparison result is outputted outside the LSI as a test terminal, thereby decreasing the number of terminals outputted outside the LSI.

However, the Patent Document 1 does not disclose a relation between the input test signal AIN and the expected value signal EXPECT. Therefore, it is not sure whether or not the test of the converted output signal of the ADC is correctly performed. Furthermore, the Patent Document 1 does not at all take into consideration the ADC test of a plurality of channels.

### SUMMARY OF THE INVENTION

According to one aspect of the present invention, an ADC test circuit comprising: an expected value generator configured to generate an expected value signal for a converted output signal of an ADC (Analog to Digital Converter); a test signal generator configured to generate an input test signal applied to the ADC based on the expected value signal; and a comparator configured to compare the converted output signal of the ADC corresponding to the applied input test signal with the expected value signal.

According to the other aspect of the present invention, an ADC test circuit comprising; an expected value generator configured to generate an expected value signal for converted output signals of a plurality of ADCs, the expected value signal being used to all the ADCs in common; a test signal generator configured to generate an input test signal applied to the ADCs based on the expected value signal; a plurality of comparators configured to compare the converted output signals of the ADCs corresponding to the applied input test signal with the expected value signal; and a conversion error detector configured to detect whether or not at least one of the ADCs makes a conversion error based on a signal indicative of the comparison result outputted from each of the comparators

According to the other aspect of the present invention, a semiconductor device comprising: a plurality of ADCs (Analog to Digital Converters) configured to perform A/D (Analog to Digital) conversion, a plurality of comparators configured to compare a respective one of a plurality of converted output signals with an expected value, the plurality of converted output signals being obtained by A/D-converting input test signals generated based on the expected value by a plurality of ADCs; and a conversion error detector configured to detect whether or not at least one of the ADCs makes a conversion error based on a signal indicative of a comparison result outputted from each of the comparators.

### BRIEF DESCRIPTION OF THE DRAWINGS

FIG. 1 is a block diagram showing a schematic structure of an ADC test circuit according to a first embodiment of the present invention.

FIG. 2 is a timing diagram showing an example of an operational timing of the ADC test circuit shown in FIG. 1.

FIG. 3 is a block diagram showing a schematic structure of an ADC test circuit according to a second embodiment of the present invention.

### DETAILED DESCRIPTION OF THE INVENTION

Hereinafter, embodiments of an ADC test circuit according to the present invention will be explained with reference to the accompanying drawings.

### First Embodiment

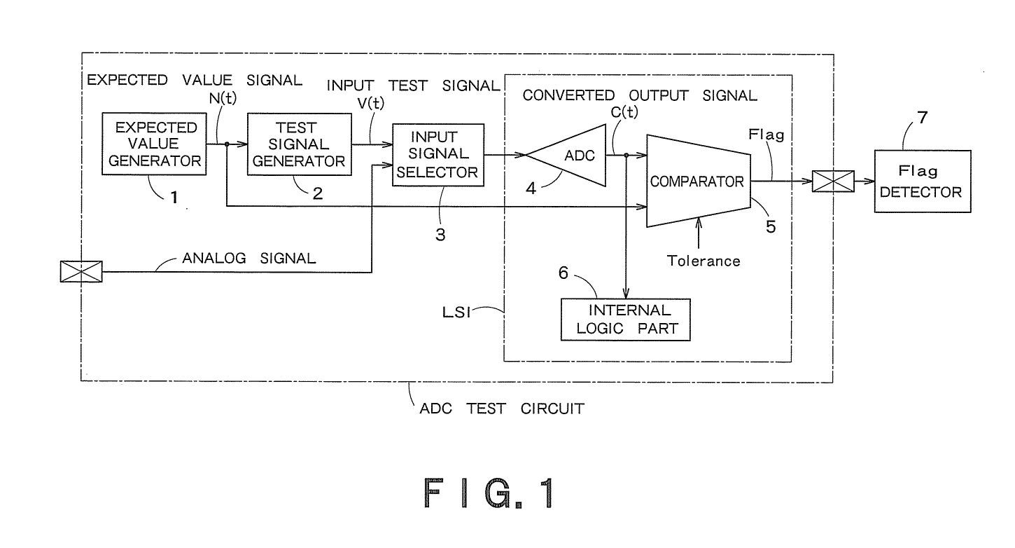

FIG. 1 is a block diagram showing a schematic structure of an ADC test circuit according to a first embodiment of the present invention. The ADC test circuit shown in FIG. 1 has an expected value generator 1, a test signal generator 2, an input signal selector 3, an ADC 4 to be tested, a comparator 5, and an internal logic part 6.

The ADC 4, the comparator 5, and the internal logic part 6 are, for example, embedded in a semiconductor chip. The other parts can be embedded in the same chip and can be composed of the other chip.

The expected value generator 1 generates an expected value signal N(t) of the ADC 4. The expected value signal N(t) is a digital signal having a plurality of bits. The test signal generator 2 generates an input test signal V(t) applied to the ADC 4 based on the expected value signal N(t). The input test signal V(t) is a voltage signal having voltage level corresponding to the bit group of the expected value signal N(t).

The input signal selector 3 selects one of the input test signal V(t) and an analog signal inputted from outside. Here, the analog signal means an analog signal (e.g. analog video signal) before A/D conversion and is inputted from outside on normal operation. The input signal selector 3 selects the input test signal V(t) when the test of the ADC 4 is performed and selects the analog signal inputted from outside during normal operation, that is, when the test of the ADC 4 is not performed.

The comparator 5 compares a converted output signal C(t) of the ADC 4 with the expected value signal N(t) when the ADC test is performed and outputs a comparison result as a Flag signal of 1 bit. The internal logic part 6 performs digital signal processing (e.g. MPEG decode processing) for the converted output signal C(t) during normal operation of the ADC 4. A Flag detector 7, which is provided outside the ADC test circuit, monitors the Flag signal outputted from the comparator 5.

Hereinafter, the explanation of the input signal selector 3 and the internal logic part 6 will be omitted because they do not directly relate to the operation of this embodiment.

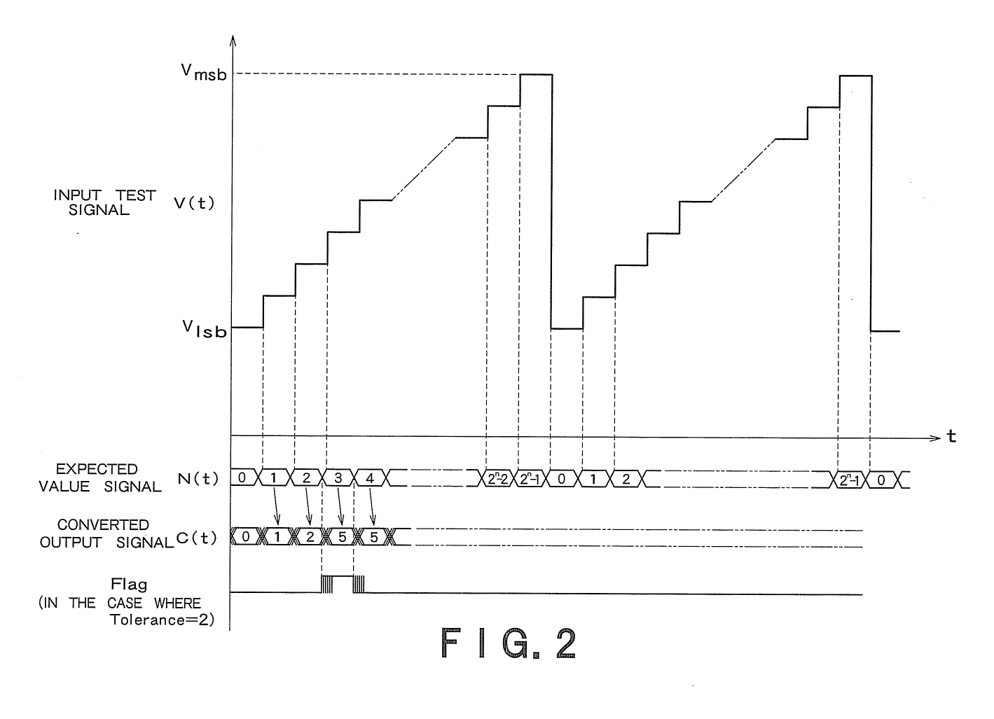

FIG. 2 is a timing diagram showing an example of an operational timing of the ADC test circuit shown in FIG. 1. The operational processing will be described referring to FIG. 2. The expected value generator 1 generates the expected value signal N(t). The expected value signal N(t) at time t is expressed by the following equation (1).

N(t)=t mod 2ⁿ (1)

Here, “n” is a resolution of the ADC 4. The expected value N(t) is the remainder of “t” divided by “2ⁿ”. The value of the expected value signal N(t) is varying from “0” to “2ⁿ−1” by turns according to the equation (1). The expected value generator 1 can be composed of a counter (e.g. an up/down counter) varying the value in a stepwise manner in synchronization with a clock signal.

The test signal generator 2 converts the expected value signal N(t) to the input test signal V(t) applied to the ADC 4 according to the following equation (2).

V(t)=(Vmsb−Vlsb)/(2ⁿ−1)*N(t)+Vlsb (2)

Here, “Vmsb” is the full scale input voltage (maximum input voltage), and “Vlsb” is the zero scale input voltage (minimum input voltage).

According to the equation (2), a ramp signal whose voltage level varies in a stepwise manner with time is generated, and one of the voltages obtained by dividing the voltage between Vlsb and Vmsb equally into “2ⁿ1” is outputted based on the expected value signal N(t).

The comparator 5 shown in FIG. 5 judges whether or not the ADC 4 makes a conversion error, and outputs the Flag signal of 1 bit indicative of the judgment result. That is, when the converted output signal C(t) of the ADC 4 and the expected value signal N(t) satisfy the following equation (3), the comparator 5 sets the Flag signal to be “0” indicative of absence of the conversion error, and when they do not satisfy the equation (3), the comparator 5 sets the Flag signal to be “1” indicative of presence of the conversion error.

|C(t)−N(t)<Tolerance (3)

Here, the Tolerance signal (error margin signal) indicative of a margin threshold of the conversion error is inputted to the comparator 5. The comparator 5 can set the lower bits of the differential absolute value between the converted output signal C(t) and the expected value signal N(t) so as not to be compared or can set a margin for the differential absolute value. Furthermore, the Tolerance signal can be an arbitrary value set from outside or a predetermined value.

FIG. 2 shows an example in the case where the Tolerance=2. In FIG. 2, N(t)=0, 1, 2 corresponds to C(t)=0, 1, 2, respectively. They satisfy the equation (3). Therefore, the value of the Flag signal is set to be “0”. However, In FIG. 2, N(t)=3 corresponds to C(t)=5. They do not satisfy the equation (3). Therefore, the value of the Flag signal is set to be “1”. If the Flag detector 7 detects that the value of the Flag signal is “1”, it can confirm that the conversion error of the ADC 4 has occurred.

The reason of setting the Tolerance signal is because the degree of precision depends on requirement specification and test circumstance and it is not always necessary to test all the bits of the ADC 4. Furthermore, because the lower bits of the ADC 4 are easy to vary due to influence of disturbance such as noises, the test can be performed avoiding the influence by setting the Tolerance signal.

As stated above, in the first embodiment, the test of the ADC 4 is performed by the ADC test circuit and the test result is outputted from the comparator 5 as the Flag signal of 1 bit. Therefore, it is not necessary to output all the bits of the converted output signal of the ADC 4 on the purpose of the ADC test. According to the first embodiment, it is possible to reduce the occurrence of the simultaneous switching noise of output buffers which are necessary to output the converted output signal of the ADC 4, and possible to perform the ADC test without worsening the characteristics of the ADC 4. Furthermore, in this embodiment, because the result of the ADC test is the Flag signal of only 1 bit, the number of the terminals necessary for the test including control signals can be drastically decreased.

Additionally, in this embodiment, when the converted output signal C(t) is compared with the expected value signal N(t) at the comparator 5, the Tolerance signal can be set on need. Therefore, the test can be performed with setting an acceptable conversion error, and practical and efficient test is feasible without being influenced by the disturbance etc.

Furthermore, in this embodiment, the input test signal V(t) applied to the ADC 4 is generated based on the expected value signal N(t) and the ADC test is performed by comparing the converted output signal C(t) of the ADC 4 with the expected value signal N(t). Therefore, it is unnecessary to separately provide the reference signal compared with the converted output signal C(t) of the ADC 4, thereby performing the ADC test at simplified structure.

As a modified example, if the input test signal V(t) is a ramp signal, it is possible to perform the ADC test over a whole area of an input dynamic range of the ADC 4, thereby testing the entire converted output of the ADC 4.

It may be possible to set the range of the input voltage of the ADC 4 not 0V to a power supply voltage but Vlsb to Vmsb, thereby also testing the ADC which does not accept 0V or the power supply voltage.

### Second Embodiment

In the first embodiment, an example of one channel ADC test has been explained. However, an ADC test circuit can perform a test of a plurality channels of ADCs. Hereinafter, this kind of ADC test will be described below.

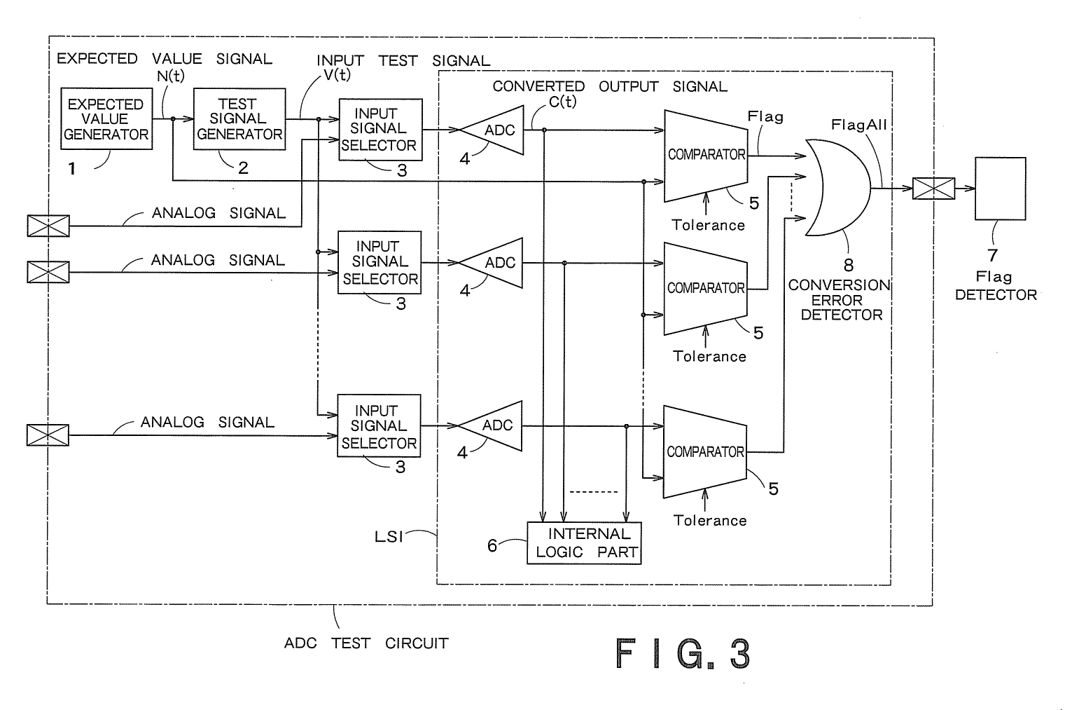

FIG. 3 is a block diagram showing a schematic structure of an ADC test circuit according to a second embodiment of the present invention. In FIG. 3, the same numerals are attached to the components common to those in FIG. 1, and the differences will be mainly explained hereinafter. The ADC test circuit of FIG. 3 has a plurality of input signal selectors 3, a plurality of ADCs 4, and a plurality of comparators 5. Furthermore, the ADC test circuit of FIG. 3 has a conversion error detector 8 to detect whether or not at least one of the ADCs 4 makes a conversion error and to output the detected result as a FlagAll signal.

The ADCs 4, the comparators 5, the internal logic part 6, and the conversion error detector 8 are, for example, embedded in a semiconductor chip. The other parts can be embedded in the same chip and can be composed of the other chip.

The processing operation of the ADC test circuit of FIG. 3 will be described below. Similarly to the first embodiment, the expected value signal V(t) and the input test signal V(t) are generated, and the input test signal V(t) common to all the ADCs 4 are inputted to the ADCs 4. Each comparator 5 sets the value of the Flag signal to be “0” when the converted output signal C(t) of the corresponding ADC 4 and the common expected value signal N(t) satisfy the equation (3) and sets the value of the Flag signal to be “1” when the converted output signal C(t) of the corresponding ADC 4 and the common expected value signal N(t) do not satisfy the equation (3).

The conversion error detector 8 sets the value of the FlagAll signal to be “1” when at least one of the ADCs 4 does not satisfy the equation (3) to determine that at least one of the ADCs 4 makes a conversion error. However, the conversion error detector 8 sets the value of the FlagAll signal to be “0” when all the ADCs 4 satisfy the equation (3) to determine that none of the ADCs 4 makes the conversion error. For example, the conversion error detector 8 can detect whether or not at least one of the ADCs 4 makes the conversion error by calculating a logical sum of the Flag signals outputted by each of the comparators 5.

When the Flag detector 7 detects that the value of the FlagAll signal becomes “1”, it can detect that at least one of the ADCs 4 makes the conversion error.

As described above, in the second embodiment, the expected value signal N(t) is common to all the ADCs 4, and it is possible to detect whether or not at least one of the ADCs 4 makes the conversion error based on the signal of 1 bit outputted by the conversion error detector 8. Therefore, it is possible to reduce the number of the signal pins necessary for the test, and to increase the number of the ADCs capable of being measured simultaneously, thereby reducing the test time (cost).

Although in above embodiments, an example of voltage-input type ADCs is explained, this invention is not limited to the voltage-input type. For example, the ADCs can be current-input type. In this case, the test signal generator 2 generates input current applied to the ADCs based on the expected value signal.

Although based on above description, those skilled in the art can figure out additional effects and variations of the present invention, the aspect of the present invention is not limited to the stated each embodiments. Various additions, alterations and partial deletions can be done to the present invention within the conceptualistic thought and purpose of the present invention drawn on the claims and the equivalents.

What is claimed is:

1. An ADC test circuit comprising:
an expected value generator configured to generate an expected value signal for a converted output signal of an ADC (Analog to Digital Converter);
a test signal generator configured to generate an input test signal applied to the ADC based on the expected value signal; and
a comparator configured to compare the converted output signal of the ADC corresponding to the applied input test signal with the expected value signal.

2. The circuit of claim 1,
wherein the comparator outputs a signal indicative of a result of comparing the converted output signal of the ADC with the expected value signal based on an error margin signal for judging an error margin between the converted output signal of the ADC and the expected value signal.

3. The circuit of claim 1,
wherein the comparator outputs a signal indicative of whether or not an absolute value of a difference between the converted output signal of the ADC and the expected value signal exceeds a predetermined threshold.

4. The circuit of claim 1,
wherein the expected value generator is a counter configured to generate the expected value signal having a plurality of bits whose value varies in a stepwise manner in synchronization with a clock signal; and
the input test signal is a ramp signal whose signal level varies in a stepwise manner.

5. The circuit of claim 1,
wherein the test signal generator generates the input test signal whose maximum value and minimum value are a maximum input signal and a minimum input signal capable of performing A/D (Analog to Digital) conversion by the ADC, respectively.

6. The circuit of claim 5,
wherein the test signal generator generates the input test signal based on a following equation (1) composing:
V(t)=(Vmsb−Vlsb)/(2n−1)*N(t)+Vlsb (1)
where the V(t) is the input test signal, the Vmsb is the maximum input signal, the Vlsb is the minimum input signal, the n is the resolution of the ADC, and the N(t) is the expected value signal.

7. An ADC test circuit comprising;
an expected value generator configured to generate an expected value signal for converted output signals of a plurality of ADCs, the expected value signal being used to all the ADCs in common;
a test signal generator configured to generate an input test signal applied to the ADCs based on the expected value signal;
a plurality of comparators configured to compare the converted output signals of the ADCs corresponding to the applied input test signal with the expected value signal; and
a conversion error detector configured to detect whether or not at least one of the ADCs makes a conversion error based on a signal indicative of the comparison result outputted from each of the comparators.

8. The circuit of claim 7,
wherein the comparator outputs a signal indicative of a result of comparing the converted output signals of the ADCs with the expected value signal based on an error margin signal for judging an error margin between the converted output signals of the ADCs and the expected value signal.

9. The circuit of claim 7,
wherein the comparators output signals indicative of whether or not an absolute value of a difference between the converted output signals of the ADCs and the expected value signal exceeds a predetermined threshold.

10. The circuit of claim 7,
wherein the conversion error detector detects whether or not at least one of the ADCs makes the conversion error by calculating a logical sum of signals outputted from each of the comparators.

11. The circuit of claim 7,
wherein the expected value generator is a counter configured to generate the expected value signal having a plurality of bits whose value varies in a stepwise manner in synchronization with a clock signal; and
the input test signal is a ramp signal whose signal level varies in a stepwise manner.

12. The circuit of claim 7,
wherein the test signal generator generates the input test signal whose maximum value and minimum value are a maximum input signal and a minimum input signal capable of performing A/D (Analog to Digital) conversion by the ADCs, respectively.

13. The circuit of claim 12,
wherein the test signal generator generates the input test signal based on a following equation (1) comprising:
V(t)=(Vmsb−Vlsb)/(2n−1)*N(t)+Vlsb (1)
where, the V(t) is the input test signal, the Vmsb is the maximum input signal, the Vlsb is the minimum input signal, the n is the resolution of the ADCs, and the N(t) is the expected value signal.

14. A semiconductor device comprising:
a plurality of ADCs (Analog to Digital Converters) configured to perform A/D (Analog to Digital) conversion,
a plurality of comparators configured to compare a respective one of a plurality of converted output signals with an expected value, the plurality of converted output signals being obtained by A/D-converting input test signals generated based on an expected value signal by a plurality of ADCs; and
a conversion error detector configured to detect whether or not at least one of the ADCs makes a conversion error based on a signal indicative of a comparison result outputted from each of the comparators.

15. The device of claim 14,
wherein the comparator outputs a signal indicative of a result of comparing the converted output signals of the ADCs with the expected value signal based on an error margin signal for judging an error margin between the converted output signals of the ADCs and the expected value signal.

16. The device of claim 14,
wherein the comparators output signals indicative of whether or not an absolute value of a difference between the converted output signals of the ADCs and the expected value signal exceeds a predetermined threshold.

17. The device of claim 14,
wherein the conversion error detector detects whether or not at least one of the ADCs makes the conversion error by calculating a logical sum of signals outputted from each of the comparators 5.

18. The device of claim 14,
wherein the expected value signal is a signal having a plurality of bits whose value varies in a stepwise manner in synchronization with a clock signal; and
the input test signal is a ramp signal whose signal level varies in a stepwise manner.

19. The device of claim 14,
wherein the input test signal is a signal whose maximum value and minimum value are a maximum input signal and a minimum input signal capable of performing A/D (Analog to Digital) conversion by the ADCs, respectively.

20. The device of claim 19,
wherein the input test signal is a signal shown in a following equation (1) comprising:
V(t)=(Vmsb−Vlsb)/(2n−1)*N(t)+Vlsb (1)
where, the V(t) is the input test signal, the Vmsb is the maximum input signal, the Vlsb is the minimum input signal, the n is the resolution of the ADCs, and the N(t) is the expected value signal.
